(19) United States
(12) Patent Application Publication
(10) Pub. No.: US 2007/0054047 A1
(43) Pub. Date: Mar. 8, 2007

(54) Method of forming a tantalum-containing layer from a metalorganic precursor

(75) Inventors: Tadahiro Ishizaka, Watervliet, NY (US); Atsushi Gomi, Rennselaer, NY (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/218,483

(22) Filed: Sep. 6, 2005

(51) Int. Cl. C23C 16/00

(52) U.S. Cl. 427/248.1

(57) ABSTRACT

A method and precursor for forming and integrating a Ta-containing layer in semiconductor processing. The tantalum precursor has the formula (CpR₁)(CpR₂)TaH(CO), where Cp is a cyclopentadienyl functional group and R₁ and R₂ are H or alkyl groups. The method includes providing a substrate in a process chamber of a deposition system, and exposing a process gas comprising the tantalum precursor to the substrate to form the Ta-containing layer. The Ta-containing layer may be treated to remove contaminants and modify the layer. The Ta-containing layer may contain tantalum metal, tantalum carbide, tantalum nitride, or tantalum carbonitride, or a combination thereof, and may be deposited in a TCVD, ALD, or PEALD process. A semiconductor device containing a Ta-containing layer formed on a patterned substrate containing one or more vias or trenches is provided.

### CROSS REFERENCE TO RELATED APPLICATIONS

The present invention is related to U.S. patent application Ser. No. 11/083,899, titled “A PLASMA ENHANCED ATOMIC LAYER DEPOSITION SYSTEM AND METHOD”, the entire contents of which are hereby incorporated by reference.

### FIELD OF THE INVENTION

The present invention relates to semiconductor processing, and more particularly, to a method for forming and integrating a tantalum-containing layer into Cu metallization applications.

### DESCRIPTION OF RELATED ART

The introduction of copper (Cu) metal into multilayer metallization schemes for manufacturing integrated circuits can necessitate the use of diffusion barriers/liners to promote adhesion and growth of the Cu layers and to prevent diffusion of Cu into the dielectric materials. Barriers/liners that may be deposited onto dielectric materials can include refractive materials, such as tungsten (W), molybdenum (Mo), and tantalum (Ta), that are non-reactive and immiscible in Cu, and can offer low electrical resistivity. Current integration schemes that integrate Cu metallization and dielectric materials can require that barrier/liner deposition processes be conducted at low temperatures, for example when integrating barrier/liners layers with temperature sensitive material layers, such as various low-dielectric constant (low-k) materials.

For example, Cu integration schemes for technology nodes less than or equal to about 100 nm can utilize processing that includes patterning a low-k inter-level dielectric, physical vapor deposition (PVD) of a Ta or TaN/Ta barrier layer onto the patterned low-k dielectric, PVD of a Cu seed layer onto the barrier layer, and electrochemical deposition (ECD) of Cu onto the Cu seed layer. Generally, Ta layers are chosen for their adhesion properties (i.e., their ability to adhere to Cu), and TaN layers are generally chosen for their barrier properties (i.e., their ability to prevent Cu diffusion into dielectric material).

Vapor deposition processes, including thermal chemical vapor deposition (TCVD) and plasma enhanced chemical vapor deposition (PECVD), are commonly utilized to deposit material along fine lines or within vias or contacts on a silicon substrate. In TCVD, a layer of material is deposited by exposing a process gas containing a precursor to a substrate, where the precursor thermally reacts in the absence of a plasma on the substrate surface to form the layer. In PECVD, plasma is utilized to alter or enhance the layer deposition mechanism. For instance, plasma excitation generally allows layer-forming reactions to proceed at temperatures that are significantly lower than those typically required to produce a similar layer by thermal CVD. In addition, plasma excitation may activate layer-forming chemical reactions that are not energetically or kinetically favored in thermal CVD. The chemical and physical properties of PECVD layers may thus be varied over a relatively wide range by adjusting process parameters.

More recently, atomic layer deposition (ALD) or plasma enhanced atomic layer deposition (PEALD), a form of CVD or more generally layer deposition, has emerged as a candidate for ultra-thin Ta-containing layer formation in front end-of-line (FEOL) operations, as well as ultra-thin Ta-containing barrier layer formation for metallization in back end-of-line (BEOL) operations. In ALD, two or more process gasses are introduced alternatingly and sequentially in order to form a material film one monolayer at a time. Such an ALD process has proven to provide improved uniformity and control in layer thickness, as well as conformality to features on which the layer is deposited. However, current ALD processes often suffer from contamination problems that affect the quality of the deposited layers, and thus the manufactured device.

For example, Ta precursors are disclosed in U.S. Pat. Nos. 6,491,978 and 6,743,473. The '978 patent discloses precursors having the formula (Cp(R)ₙ)ₓM(CO)_{y-x}, and the '473 patent discloses precursors having the formula (Cp(R)ₙ)ₓM(H)_{y-x}, where Cp is a cyclopentadienyl group. However, the vapor pressures of these precursors are typically no more than about 0.1 torr at 100° C., which limits their utility in depositing Ta films.

Moreover, these precursors do not exclude the use of halogens and/or nitrogen. The present inventors have recognized that the use of halogen-containing precursors commonly results in high halogen levels in the Ta-containing layers that are unacceptable for integration with other layers in an integrated circuit. Further, N has been included in commercial Ta precursors to provide stability, with the expectation that during CVD the N would react with H to form NH₃ gas. However, the present inventors have found that without plasma excitation during CVD insufficient N is removed as NH₃. Instead the N collects in the deposited film as TaN, which has poor adhesion properties.

Ta precursors that are free of halogen and of N and that have higher vapor pressures are needed, particularly those that can be used in Ta deposition processes that are easily integrated with subsequent Cu deposition processes.

The present inventors directed vendors to search for halogen and N free Ta compounds with vapor pressures high enough that the compounds could serve as precursors in chemical vapor deposition processes. After reviewing a series of candidate materials, the present inventors discovered that certain metalorganic Ta compounds provide significant advantages relative to conventional materials as CVD precursors.

### SUMMARY OF THE INVENTION

Embodiments of the invention are directed to addressing any of the above-described and/or other problems with deposition of Ta-containing layers. According to one embodiment of the invention, a non-halogen-containing and non-nitrogen-containing tantalum precursor is utilized to deposit a Ta-containing layer. The Ta-containing layer can be integrated into semiconductor processing as a barrier layer in Cu metallization schemes. The Ta-containing layer may contain tantalum metal, or tantalum carbide, or a combination thereof, and may be deposited by a process such as TCVD, ALD, or PEALD. After deposition, the Ta-containing layer can be processed so as to include tantalum nitride or tantalum carbonitride. The tantalum precursor can contain Ta, a H ligand and a CO ligand. The CO ligand provides the tantalum precursor with improved thermal stability. The tantalum precursor can have the formula (CpR₁)(CpR₂)TaH(CO), where Cp is a cyclopentadienyl functional group and R₁ and R₂ are H or alkyl groups.

According to one embodiment of the invention, the method includes providing a substrate in a process chamber of a deposition system, exposing a process gas containing the (CpR₁)(CpR₂)TaH(CO) precursor to the substrate to form a Ta-containing layer. According to another embodiment of the invention, the Ta-containing layer may be treated to remove contaminants and modify the deposited layer.

According to yet another embodiment of the invention, the method includes providing a substrate in a process chamber of a deposition system, pretreating the substrate, exposing a process gas containing a (CpR₁)(CpR₂)TaH(CO) precursor to the substrate to form a Ta-containing layer, posttreating the Ta-containing layer, depositing a seed layer on the posttreated layer, and depositing a Cu layer on the seed layer.

A semiconductor device containing a patterned substrate is provided. The patterned substrate contains one or more vias or trenches, or combinations thereof, a Ta-containing layer formed by exposure to a process gas containing a (CpR₁)(CpR₂)TaH(CO) precursor, a seed layer formed on the Ta-containing layer, and a bulk Cu layer formed on the seed layer.

### BRIEF DESCRIPTION OF THE DRAWINGS

In the accompanying drawings:

FIG. 1A depicts a schematic view of a (CpR₁)(CpR₂)TaH(CO) precursor according to an embodiment of the invention;

FIG. 1B depicts a schematic view of a deposition system according to an embodiment of the invention;

FIG. 2 is a process flow diagram for depositing a Ta-containing layer on a substrate according to an embodiment of the invention;

FIGS. 3A and 3B are process flow diagrams for depositing a Ta-containing layer on a substrate according to embodiments of the invention;

FIG. 3C is a timing diagram for a PEALD process in according to an embodiment of the invention;

FIGS. 4A-4D depict a schematic view of formation of a Ta-containing layer on a substrate according to embodiments of the invention;

FIGS. 5A-5C are process flow diagrams for depositing a Ta-containing layer on a substrate and treating the Ta-containing layer according to embodiments of the invention;

FIG. 6 is a process flow diagram for integrating a Ta-containing layer with Cu metallization according to an embodiment of the invention;

FIG. 7 depicts schematically integration of a Ta-containing layer with Cu metallization according to an embodiment of the invention; and

FIG. 8 depicts a schematic view a Ta-containing layer integrated with Cu metallization of a semiconductor structure according to an embodiment of the invention.

### DETAILED DESCRIPTION OF SEVERAL EMBODIMENTS

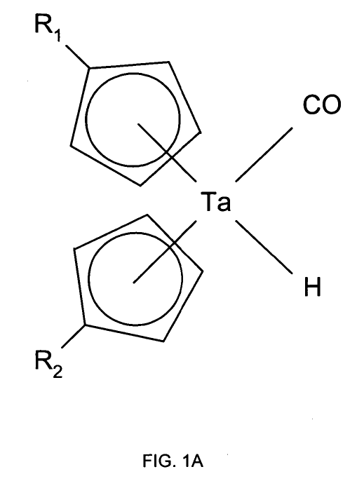

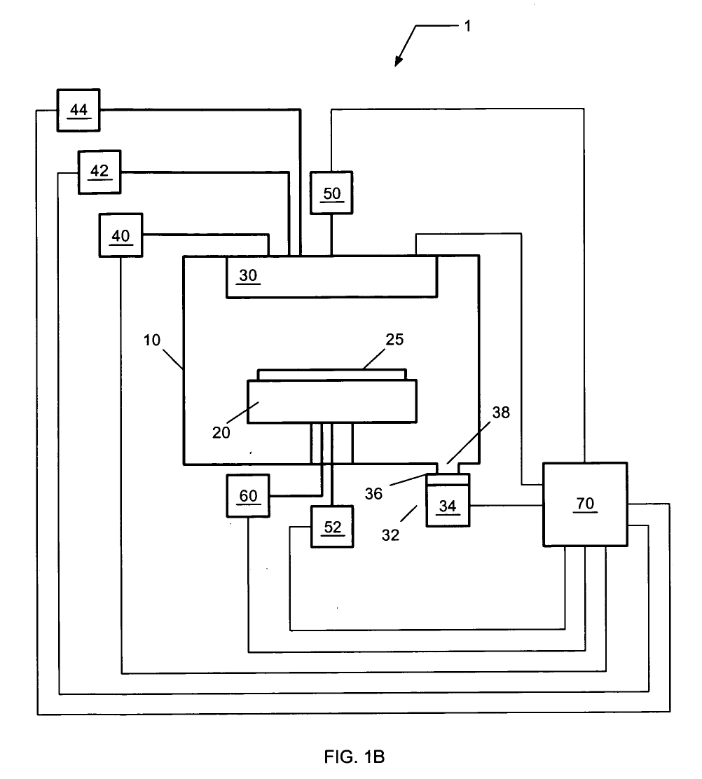

Embodiments of the invention provide a method and precursor for forming and integrating a Ta-containing layer in semiconductor processing. The tantalum precursor can contain Ta, a H ligand and a CO ligand. The CO improves thermal stability. The CO does not dissociate appreciably during deposition and thus does not significantly oxidize a Ta-containing layer formed from the tantalum precursor or significantly raise the electrical resistivity of the Ta-containing layer. The tantalum precursor can have the formula (CpR₁)(CpR₂)TaH(CO), where Cp is a cyclopentadienyl functional group and R₁ and R₂ are H or alkyl groups. FIG. 1A depicts a schematic view of a (CpR₁)(CpR₂)TaH(CO) precursor.

An embodiment of the invention includes providing a substrate in a process chamber of a deposition system, exposing a process gas comprising the tantalum precursor to the substrate to form the Ta-containing layer. The Ta-containing layer may be treated to remove contaminants and modify the layer. The Ta-containing layer may contain tantalum metal, tantalum carbide, tantalum nitride, or tantalum carbonitride, or a combination thereof, and may be deposited a TCVD, ALD, or PEALD process.

In the following description, in order to facilitate a thorough understanding of the invention and for purposes of explanation and not limitation, specific details are set forth, such as a particular geometry of the deposition system and descriptions of various components. However, it should be understood that the invention may be practiced in other embodiments that depart from these specific details.

Referring now to the drawings, FIG. 1B depicts a schematic view of a deposition system 1 for depositing and treating Ta-containing layer on a substrate according to one embodiment. For example, during the metallization of inter-connect and intra-connect structures for semiconductor devices in back-end-of-line (BEOL) operations, a thin conformal Ta-containing barrier layer may be deposited on wiring trenches or vias to minimize the migration of metal into the inter-level or intra-level dielectric. Further, a thin conformal Ta-containing layer may be deposited on wiring trenches or vias to provide a film with acceptable adhesion properties for bulk metal fill, or a thin conformal adhesion layer may be deposited on wiring trenches or vias to provide a film with acceptable adhesion properties for metal seed deposition. In front-end-of line (FEOL) operations, the deposition system 1 may be used to deposit an ultra thin Ta-containing gate layer.

The deposition system 1 comprises a process chamber 10 having a substrate holder 20 configured to support a substrate 25, upon which the thin Ta-containing layer is formed. The process chamber 10 further comprises an upper assembly 30 coupled to a first process material supply system 40, a second process material supply system 42, and a purge gas supply system 44. Additionally, the deposition system 1 comprises a first power source 50 coupled to the process chamber 10 and configured to generate plasma in the process chamber 10, and a substrate temperature control system 60 coupled to substrate holder 20 and configured to elevate and control the temperature of substrate 25. Additionally, deposition system 1 comprises a controller 70 that can be coupled to process chamber 10, substrate holder 20, upper assembly 30, first process material supply system 40, second process material supply system 42, purge gas supply system 44, first power source 50, and substrate temperature control system 60.

Alternately, or in addition, controller 70 can be coupled to one or more additional controllers/computers (not shown), and controller 70 can obtain setup and/or configuration information from an additional controller/computer.

In FIG. 1B, singular processing elements (10, 20, 30, 40, 42, 44, 50, and 60) are shown, but this is not required for the invention. The deposition system 1 can comprise any number of processing elements having any number of controllers associated with them in addition to independent processing elements.

The controller 70 can be used to configure any number of processing elements (10, 20, 30, 40, 42, 44, 50, and 60), and the controller 70 can collect, provide, process, store, and display data from processing elements. The controller 70 can comprise a number of applications for controlling one or more of the processing elements. For example, controller 70 can include a graphic user interface (GUI) component (not shown) that can provide easy to use interfaces that enable a user to monitor and/or control one or more processing elements.

Referring still to FIG. 1B, the deposition system 1 may be configured to process 200 mm substrates, 300 mm substrates, or larger-sized substrates. In fact, it is contemplated that the deposition system may be configured to process substrates, wafers, or LCDs regardless of their size, as would be appreciated by those skilled in the art. Therefore, while embodiments of the invention will be described in connection with the processing of a semiconductor substrate, the invention is not limited solely thereto.

The first process material supply system 40 and the second process material supply system 42 are configured to alternatingly introduce a first process material to process chamber 10 and a second process material to process chamber 10. The alternation of the introduction of the first material and the introduction of the second material can be cyclical, or it may be acyclical with variable time periods between introduction of the first and second materials. The first process material can, for example, comprise a Ta-containing precursor, such as a composition having the Ta species found in the layer formed on substrate 25. For instance, the layer precursor can originate as a solid phase, a liquid phase, or a gaseous phase, and it may be delivered to process chamber 10 in a process gas with or without the use of a carrier gas. The second process material can, for example, comprise a reducing agent, which may also include atomic or molecular species found in the film formed on substrate 25. For instance, the reducing agent can originate as a solid phase, a liquid phase, or a gaseous phase, and it may be delivered to process chamber 10 in a gaseous phase with or without the use of a carrier gas.

Additionally, the purge gas supply system 44 can be configured to introduce a purge gas to process chamber 10. For example, the introduction of purge gas may occur between introduction of the first process material and the second process material to process chamber 10, or following the introduction of the second process material to process chamber 10, respectively. The purge gas can comprise an inert gas, such as a noble gas (i.e., helium, neon, argon, xenon, krypton), or nitrogen, or hydrogen.

Referring still to FIG. 1B, the deposition system 1 comprises a plasma generation system configured to generate a plasma during at least a portion of the alternating introduction of the first process material and the second process material to process chamber 10. The plasma generation system can include a first power source 50 coupled to the process chamber 10, and configured to couple power to the first process material, or the second process material, or both in process chamber 10. The first power source 50 may be a variable power source and may include a radio frequency (RF) generator and an impedance match network, and may further include an electrode through which RF power is coupled to the plasma in process chamber 10. The electrode can be formed in the upper assembly 30, and it can be configured to oppose the substrate holder 20. The impedance match network can be configured to optimize the transfer of RF power from the RF generator to the plasma by matching the output impedance of the match network with the input impedance of the process chamber, including the electrode, and plasma. For instance, the impedance match network serves to improve the transfer of RF power to plasma in plasma process chamber 10 by reducing the reflected power. Match network topologies (e.g. L-type, π-type, T-type, etc.) and automatic control methods are well known to those skilled in the art.

Alternatively, the first power source 50 may include a radio frequency (RF) generator and an impedance match network, and may further include an antenna, such as an inductive coil, through which RF power is coupled to plasma in process chamber 10. The antenna can, for example, include a helical or solenoidal coil, such as in an inductively coupled plasma source or helicon source, or it can, for example, include a flat coil as in a transformer coupled plasma source.

Alternatively, the first power source 50 may include a microwave frequency generator, and may further include a microwave antenna and microwave window through which microwave power is coupled to plasma in process chamber 10. The coupling of microwave power can be accomplished using electron cyclotron resonance (ECR) technology, or it may be employed using surface wave plasma technology, such as a slotted plane antenna (SPA). Details on plasma processing systems having a SPA plasma source are described in co-pending European Patent Application EP1361605A1, titled “METHOD FOR PRODUCING MATERIAL OF ELECTRONIC DEVICE”, and copending U.S. patent application Ser. No. 11/083,899, titled “A PLASMA ENHANCED ATOMIC LAYER DEPOSITION SYSTEM AND METHOD”, the entire contents of which are hereby incorporated by reference.

Optionally, the deposition system 1 comprises a substrate bias generation system configured to generate or assist in generating a plasma during at least a portion of the alternating introduction of the first process material and the second process material to process chamber 10. The substrate bias system can include a substrate power source 52 coupled to the process chamber 10, and configured to couple power to substrate 25. The substrate power source 52 may include a radio frequency (RF) generator and an impedance match network, and may further include an electrode through which RF power is coupled to substrate 25. The electrode can be formed in substrate holder 20. For instance, substrate holder 20 can be electrically biased at a RF voltage via the transmission of RF power from a RF generator (not shown) through an impedance match network (not shown) to substrate holder 20. A typical frequency for the RF bias can range from about 0.1 MHz to about 100 MHz. RF bias systems for plasma processing are well known to those skilled in the art. Alternately, RF power is applied to the substrate holder electrode at multiple frequencies.

Although the plasma generation system and the optional substrate bias system are illustrated in FIG. 1B as separate entities, they may indeed comprise one or more power sources coupled to substrate holder 20.

Still referring to FIG. 1B, deposition system 1 comprises substrate temperature control system 60 coupled to the substrate holder 20 and configured to elevate and control the temperature of substrate 25. Substrate temperature control system 60 comprises temperature control elements, such as a cooling system including a re-circulating coolant flow that receives heat from substrate holder 20 and transfers heat to a heat exchanger system (not shown), or when heating, transfers heat from the heat exchanger system. Additionally, the temperature control elements can include heating/cooling elements, such as resistive heating elements, or thermoelectric heaters/coolers, which can be included in the substrate holder 20, as well as the chamber wall of the processing chamber 10 and any other component within the deposition system 1.

In order to improve the thermal transfer between substrate 25 and substrate holder 20, substrate holder 20 can include a mechanical clamping system, or an electrical clamping system, such as an electrostatic clamping system, to affix substrate 25 to an upper surface of substrate holder 20. Furthermore, substrate holder 20 can further include a substrate backside gas delivery system configured to introduce gas to the back-side of substrate 25 in order to improve the gas-gap thermal conductance between substrate 25 and substrate holder 20. Such a system can be utilized when temperature control of the substrate is required at elevated or reduced temperatures. For example, the substrate backside gas system can comprise a two-zone gas distribution system, wherein the helium gas gap pressure can be independently varied between the center and the edge of substrate 25. In one example, the temperature of the substrate 25 can be rapidly raised/lowered by controlling the thermal conductance between the substrate 25 and substrate holder 20 by de-energizing/energizing the electrical clamping system and/or removing/supplying the back-side gas. The rapid raising/lowering of the substrate temperature can be performed without significantly varying the temperature of the substrate holder 20.

Furthermore, the process chamber 10 is further coupled to a pressure control system 32, including a vacuum pumping system 34 and a valve 36, through a duct 38, wherein the pressure control system 34 is configured to controllably evacuate the process chamber 10 to a pressure suitable for forming the thin film on substrate 25, and suitable for use of the first and second process materials.

The vacuum pumping system 34 can include a turbo-molecular vacuum pump (TMP) or a cryogenic pump capable of a pumping speed up to about 5000 liters per second (and greater) and valve 36 can include a gate valve for throttling the chamber pressure. In conventional plasma processing devices utilized for dry plasma etch, a 300 to 5000 liter per second TMP is generally employed. Moreover, a device for monitoring chamber pressure (not shown) can be coupled to the processing chamber 10. The pressure measuring device can be, for example, a Type 628B Baratron absolute capacitance manometer commercially available from MKS Instruments, Inc. (Andover, Mass.).

Still referring to FIG. 1B, controller 70 can comprise a microprocessor, memory, and a digital I/O port capable of generating control voltages sufficient to communicate and activate inputs to deposition system 1 as well as monitor outputs from deposition system 1. Moreover, the controller 70 may be coupled to and may exchange information with the process chamber 10, substrate holder 20, upper assembly 30, first process material supply system 40, second process material supply system 42, purge gas supply system 44, first power source 50, second power source 52, substrate temperature controller 60, and pressure control system 32. For example, a program stored in the memory may be utilized to activate the inputs to the aforementioned components of the deposition system 1 according to a process recipe in order to perform an etching process, or a deposition process. One example of the controller 70 is a DELL PRECISION WORKSTATION 610™, available from Dell Corporation, Austin, Tex.

However, the controller 70 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 70 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 70, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 70 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 70.

The controller 70 may be locally located relative to the deposition system 1, or it may be remotely located relative to the deposition system 1. For example, the controller 70 may exchange data with the deposition system 1 using at least one of a direct connection, an intranet, the Internet and a wireless connection. The controller 70 may be coupled to an intranet at, for example, a customer site (i.e., a device maker, etc.), or it may be coupled to an intranet at, for example, a vendor site (i.e., an equipment manufacturer). Additionally, for example, the controller 70 may be coupled to the Internet. Furthermore, another computer (i.e., controller, server, etc.) may access, for example, the controller 70 to exchange data via at least one of a direct connection, an intranet, and the Internet. As also would be appreciated by those skilled in the art, the controller 70 may exchange data with the deposition system 1 via a wireless connection.

Embodiments of the invention may be carried out utilizing the deposition system 1 of FIG. 1B but this is not required for embodiments of the invention as other deposition systems may be utilized without departing from the scope of the invention. For example, other deposition systems that may be utilized are described in copending U.S. patent application Ser. No. 11/083,899.

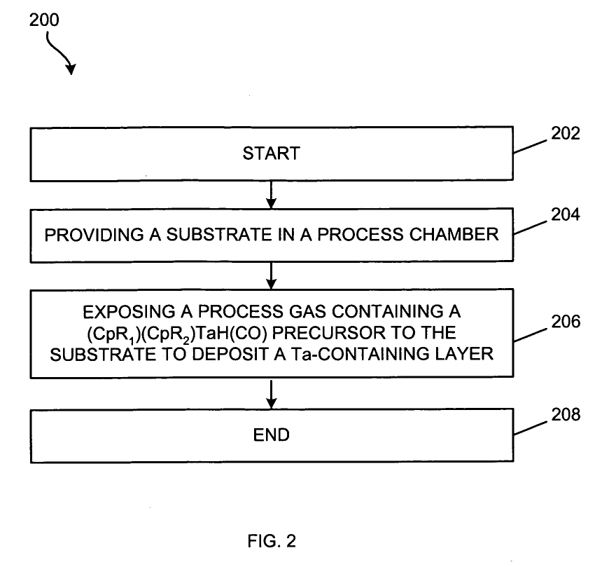

FIG. 2 is a process flow diagram for depositing a Ta-containing layer on a substrate according to an embodiment of the invention. The process 200 starts in step 202. In step 204, a substrate is provided in a process chamber of a deposition system. For example, the deposition system can include the deposition system 1 described above in FIG. 1B. The substrate can, for example, be a semiconductor substrate, such as a Si substrate. A Si substrate can be of n- or p-type, depending on the type of device being formed. According to an embodiment of the invention, as further described in FIG. 8, the substrate may be a patterned substrate, for example a semiconductor wafer used for manufacturing semiconductor devices, containing one or more vias or trenches, or combinations thereof.

In step 206, a process gas containing a tantalum precursor containing Ta, a H ligand and a CO ligand is exposed to the substrate to form a Ta-containing layer in TCVD process. The tantalum precursor can have the general formula (CpR₁)(CpR₂)TaH(CO). Preferably the tantalum precursor has a vapor pressure at 100° C. in the range of from 0.1 to 3 torr. According to an embodiment of the invention, the process gas may be thermal. Alternately, the process gas may be plasma excited. According to embodiments of the invention, the Ta-containing layer may contain tantalum metal (Ta), tantalum carbide (TaCₓ), tantalum carbonitride (TaCₓN_{y}), or tantalum nitride (TaN_{y}). According to embodiments of the invention, Cp is a cyclopentadienyl functional group, and R₁ and R₂ may be any combinations of H and alkyl groups. R₁ and R₂ may be C₁-C₈ alkyl groups, including linear and/or branched alkyl groups having from 1 to 8 carbon atoms. For example, the alkyl groups can be methyl (i.e., Me or CH₃—), ethyl (i.e., Et or CH₃CH₂—), n-propyl (i.e., ⁿPr or CH₃CH₂CH₂—), isopropyl (i.e., ⁱPr or (CH₃)₂CH—), or tert-butyl (i.e., ^{t}Bu or (CH₃)₃C—) groups, but embodiments of the invention are not limited to those alkyl groups as the (CpR₁)(CpR₂)TaH(CO) precursor may contain other R₁, R₂ alkyl groups.

Preferably, during deposition of the Ta-containing layer the process gas and the tantalum precursor are free of N and of halogens, such as F and Cl.

The N content of the Ta-containing film, as deposited, is preferably 5 atomic % or less. In contrast, the N content is 25 atomic % or more in Ta-containing films CVD deposited from commercially available Ta precursors containing N. Excess N (e.g. TaN) in a Ta-containing film can lead to poor adhesion properties. In contrast, a Ta-containing film containing TaC has good adhesion properties.

To minimize impurity concentrations in the deposited Ta-containing film, the concentration of alkaline earth metals, Fe, Cr, N₁, H₂O, F and Cl in the CVD precursor is preferably 5 ppb or less.

According to one embodiment of the invention, the thermal decomposition temperature of the tantalum precursor can be in the range of from 200 to 500° C.

According to one embodiment of the invention, the tantalum precursor may be (CpCH₂CH₃)₂TaH(CO). The (CpCH₂CH₃)₂TaH(CO) precursor is a liquid at room temperature with vapor pressures of 0.1 Torr at 108° C. and 1 Torr at 150° C. Thermal stability experiments showed no change in the precursor as measured by nuclear magnetic resonance (NMR) after 24 hours at 170° C. and after 96 hours at 140° C. Thermogravimetry (TG) and differential scanning calorimetry (DSC) data showed onset of decomposition of the (CpCH₂CH₃)₂TaH(CO) precursor at about 245° C. with a DSC maximum peak intensity at about 312° C. The relatively high vapor pressure of the precursor coupled with the good thermal stability allows for efficient transport of the precursor vapor to the process chamber where a Ta-containing layer is deposited on a substrate.

According to another embodiment of the invention, the tantalum precursor may be (Cp)₂TaH(CO). The (Cp)₂TaH(CO) precursor is a solid at room temperature with a melting point of 159° C. DSC data showed a maximum peak intensity at about 278° C.

The process gas can be formed by heating a (CpR₁)(CpR₂)TaH(CO) precursor to form the precursor vapor and flowing a carrier gas over or through the solid or liquid precursor. The carrier gas can, for example, be an inert gas such as N₂ or a noble gas (e.g., Ar). Alternately, in the case of a liquid precursor, the process gas can be formed using a liquid delivery system having a vaporizer. According to an embodiment of the invention, the substrate is maintained at a temperature between about 150° C. and about 600° C. in step 206 during exposure of the tantalum precursor to the substrate. Alternately, the substrate temperature can be between about 250° C. and about 400° C. The process gas may be exposed to the substrate at a process chamber pressure between about 0.1 Torr and about 760 Torr. Alternately, the process pressure may be between about 0.5 Torr and about 100 Torr. Yet alternately, the process pressure may be between about 1 Torr and about 20 Torr.

In one example, a process gas containing (CpCH₂CH₃)₂TaH(CO) precursor, Ar carrier gas, and Ar dilution gas was exposed to a SiO₂ layer on a Si substrate maintained at 510° C. An amorphous Ta-containing layer was deposited at a deposition rate of about 2.4 nm/min onto the SiO₂ layer. The deposition rate decreased with decreasing temperature and was about 0.04 nm/min at 406° C. and about 0.02 nm/min at 357° C. and 306° C. The crystallographic orientation of the Ta-containing layer was measured by X-ray diffraction (XRD).

As would be appreciated by those of ordinary skill in the art, each of the steps or stages in process flow diagrams illustrating embodiments of the invention may encompass one or more separate steps and/or operations. For example, the recitation of only four steps in 202, 204, 206, 208 in the process flow diagram of FIG. 2 should not be understood to limit the method of the present invention solely to four steps or stages. For example, one or more purging and/or pump down steps may be performed. Moreover, each representative step or stage 202, 204, 206, 208 should not be understood to be limited to only a single process.

According to another embodiment of the invention, the process gas can contain (CpR₁)(CpR₂)TaH(CO) precursor vapor and a reducing gas. Exemplary reducing gas includes H₂, SiH₄, B₂H₆, or HCOOH, or a combination thereof, but embodiments of the invention are not limited to these exemplary gases as other reducing gases capable of reducing a (CpR₁)(CpR₂)TaH(CO) precursor may be used.

According to another embodiment of the invention, the process gas can contain (CpR₁)(CpR₂)TaH(CO) precursor vapor and a nitrogen-containing gas. Exemplary nitrogen-containing gases include NH₃, N₂H₄, NH(CH₃)₂, or H₂N₂HCH₃, or a combination thereof.

In embodiments, the process gas can be plasma excited.

According to one embodiment of the invention, a second Ta precursor may be added to a process containing (CpR₁)(CpR₂)TaH(CO) precursor vapor. It is contemplated that adding a second Ta precursor with a higher activation energy for desorption than (CpR₁)(CpR₂)TaH(CO) (˜9.2 kcal/mol) may provide an adsorption site on the substrate for (CpR₁)(CpR₂)TaH(CO). In one example, the second Ta precursor may be TAIMATA (tertiaryamylimido-tris-dimethylamidotantalum, Ta(NC(CH₃)₂C₂H₅)(N(CH₃)₂)₃) with an activation energy of about 14.8 kcal/mol.

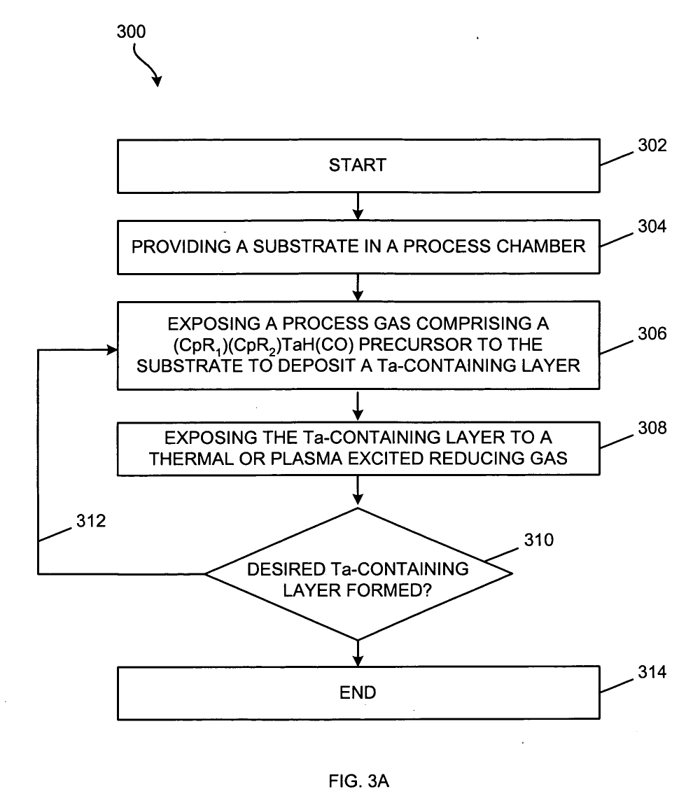

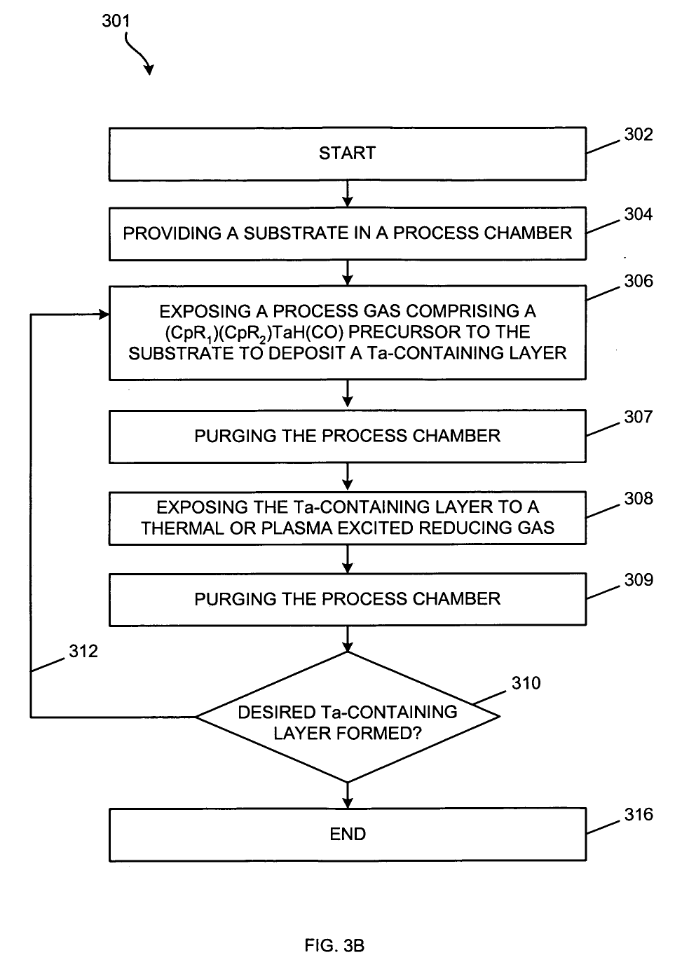

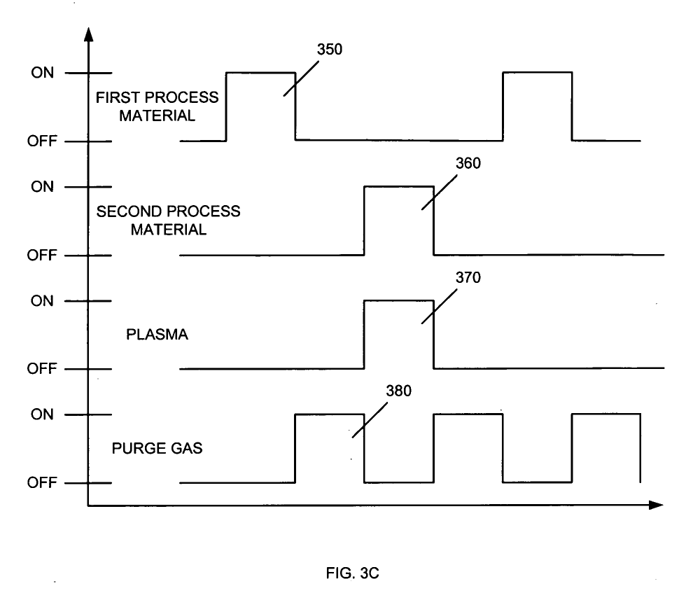

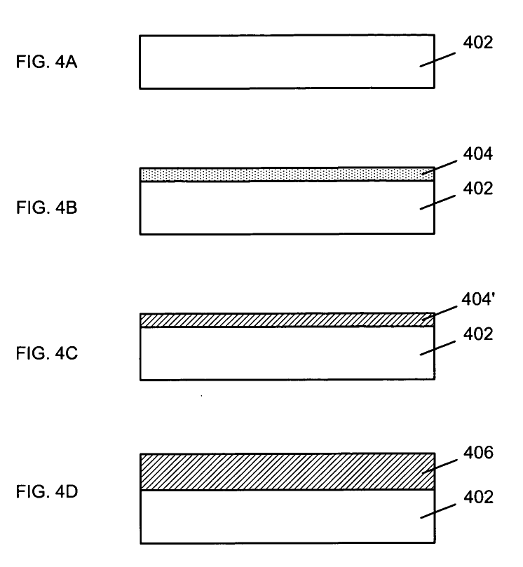

Referring now to FIGS. 3A and 4, FIG. 3A is a process flow diagram for depositing a Ta-containing layer on a substrate and FIGS. 4A-4D depict a schematic view of formation of a Ta-containing layer on a substrate according to an embodiment of the invention. The process 300 starts in step 302. In step 304, a substrate 402 shown in FIG. 4A is provided in a process chamber of a deposition system, and in step 306, a process gas containing a tantalum precursor with a general formula (CpR₁)(CpR₂)TaH(CO) is exposed to the substrate 402 to form a Ta-containing layer 404 on the substrate 402 as shown in FIG. 4B. The (CpR₁)(CpR₂)TaH(CO) precursor and the process gas were discussed in detail above in reference to FIG. 2. The substrate 402 may be maintained a temperature that enables ALD processing, where a layer is formed on the substrate one monolayer at a time. Alternately, the substrate 402 may be maintained at a temperature where a Ta-containing multilayer is formed during the exposure step 306.

In step 308, the Ta-containing layer 404 is exposed to a reducing gas to form a Ta-containing layer 404′ as shown in FIG. 4C. According to one embodiment of the invention, the reducing gas may be thermal (non-plasma) reducing gas and may include H₂, SiH₄, Si₂H₆, B₂H₆, or HCOOH, or a combination thereof, but embodiments of the invention are not limited to these exemplary gases as other reducing gases capable of reducing the Ta-containing layer 404 may be used. The reducing gas may further contain N₂, a noble gas, or a combination thereof. According to another embodiment of the invention, the reducing gas may contain plasma excited hydrogen-containing gas. The plasma excited hydrogen-containing gas may contain H₂ and a noble gas. According to yet another embodiment of the invention, the thermal reducing gas may contain a nitrogen-containing gas can, for example, contain NH₃, N₂H₄, NH(CH₃)₂, or H₂N₂HCH₃, or a combination thereof. The nitrogen-containing gas may further contain N₂, a noble gas, or a combination thereof. According to still another embodiment of the invention, the reducing gas may contain plasma excited nitrogen-containing gas. The plasma excited nitrogen-containing gas can, for example, contain N₂, NH₃, or N₂H₄, or a combination thereof. The plasma excited nitrogen-containing gas may further contain N₂, a noble gas, or a combination thereof.

Step 308 is carried out for a time period that results in the desired reduction of the Ta-containing layer. The role of the reducing step 308 may include removal of contaminants from the Ta-containing layer after partial decomposition of the tantalum precursor on the substrate 402 in the exposing step 306 and other contaminants present on the Ta-containing layer. In addition, in the case of a nitrogen-containing gas, the reducing step 308 can be utilized to incorporate nitrogen into the Ta-containing layer to form a TaCₓN_{y} or TaN_{y} layer.

If a Ta-containing layer 404′ with a desired thickness has not been formed in step 308, a decision is made in step 310 to repeat at least once the exposing steps 306 and 308, as shown by the process flow step 312, or, if the desired Ta-containing layer has been formed, to end the process 300 in step 314. Thus, the steps 306 and 308 may be repeated at least once to build up a Ta-containing layer with a desired thickness. FIG. 4D schematically shows a thick Ta-containing layer 406 following multiple exposure cycles. According to an embodiment of the invention, the thickness of the Ta-containing layer 406 can be between about 0.5 nm and about 10 nm. Alternately, the thickness can be between about 1 nm and about 5 nm. Yet alternately, the thickness can be between about 2 nm and about 4 nm.

FIG. 3B is a process flow diagram for depositing a Ta-containing layer on a substrate according to another embodiment of the invention. The process 301 contains the steps of the ALD or PEALD process 300 described above in reference to FIG. 3A and, in addition, contains purging steps 307 and 309 that are performed after the exposing steps 306 and 308, respectively. The purging step 307 removes unreacted (CpR₁)(CpR₂)TaH(CO) precursor and reaction by-products from the process chamber, and the purging step 309 removes the reducing gas and any by-products from the process chamber. The purge gas can, for example, contain an inert gas such as N₂ or a noble gas. Furthermore, one or more of the purge steps 307 and 309 may be replaced or complimented with pump down steps where no purge gas is flowed.

Still referring to FIG. 3B, in one example, the time duration of exposure step 306 can be about 3 seconds, the time duration of purge step 307 can be about 1 second, the time duration of the plasma exposure step 308 can be about 10 sec, and the time duration of purge step 309 can be about 3 seconds. However, the time durations of the various steps of the process 300 are expected to vary depending on the substrate temperature, process chamber pressure, and gas composition. In one example, TaCₓ layers containing both (111) and (200) crystallographic orientations were deposited at substrate temperatures of 197° C. and 283° C. using the process flow of FIG. 3B.

FIG. 3C is a timing diagram for an ALD or PEALD process depicted in FIG. 3B according to an embodiment of the invention. As seen in FIG. 3C, a first process material (e.g., process gas containing (CpR₁)(CpR₂)TaH(CO) vapor) is introduced to process chamber 10 of FIG. 1B for a first period of time 350 in order to cause adsorption of the Ta-precursor on exposed surfaces of substrate 25, then the process chamber 10 is purged with a purge gas for a second period of time 380. Thereafter, a second process material (e.g., reducing gas) is introduced to process chamber 10 for a third period of time 360 while power is coupled through the upper assembly 30 from the first power source 50 to the reducing gas as shown by 370. The coupling of power to the reducing gas heats the reducing gas, thus causing ionization and/or dissociation of the reducing gas in order to form a radical that chemically reacts with the Ta-precursor adsorbed on substrate 25. When substrate 25 is heated to an elevated temperature, the surface chemical reaction facilitates the formation of the desired layer. The process chamber 10 is purged with a purge gas for a fourth period of time. The introduction of the first and second process materials, and the formation of plasma can be repeated any number of times to produce a Ta-containing layer of desired thickness on the substrate.

While FIG. 3C shows plasma generation only during the reduction gas period, a plasma may also be generated during the first process material period in order to facilitate adsorption of the first process material to the substrate surface. Moreover, although the second process material time period 360 and the plasma time period 370 are shown in FIG. 3C to exactly correspond to one another, it is sufficient for purposes of embodiments of the present invention that such time periods merely overlap, as would be understood by one of ordinary skill in the art.

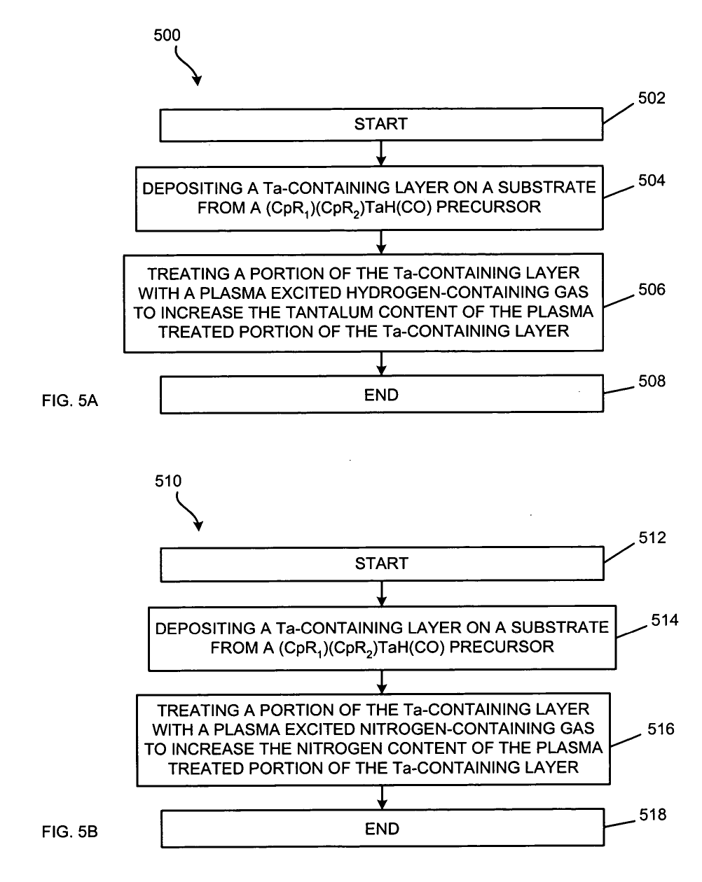

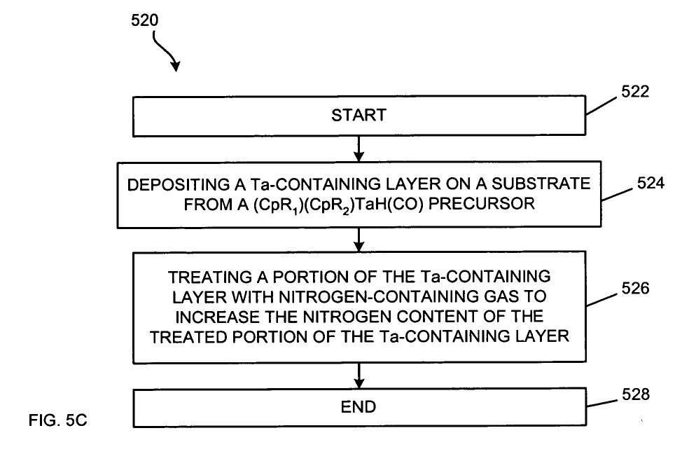

FIGS. 5A-5C are process flow diagrams for depositing a Ta-containing layer on a substrate and treating the Ta-containing layer to modify at least a portion of the Ta-containing layer prior to integration with Cu metallization. In one example, a TaCₓ layer may be exposed to a reducing plasma to increase the Ta content of the treated portion of the TaCₓ layer, thereby forming a Ta/TaCₓ bilayer. It is contemplated that a Ta/TaCₓ bilayer formed according to embodiments of the invention may have excellent diffusion barrier properties in Cu metallization by combining the adhesion properties of Ta to Cu metal and the ability of TaCₓ to prevent Cu diffusion into underlying dielectric material.

In FIG. 5A, the process 500 starts in step 502. In step 504, a Ta-containing layer is deposited on a substrate from a process gas containing a (CpR₁)(CpR₂)TaH(CO) precursor. The Ta-containing layer may be deposited by any of the processes 200, 300, 301 described in reference to FIGS. 2-3. In step 506, a portion of the Ta-containing layer is treated with a plasma excited hydrogen-containing gas to modify the Ta-containing layer. The hydrogen-containing gas increases the tantalum content of the plasma treated portion of the Ta-containing layer. The plasma excited hydrogen-containing gas can contain H₂ and a noble gas such as Ar. In one example, the Ta-containing layer can be a TaCₓ layer. The plasma treatment can remove carbon and impurities such as oxygen from the Ta-containing layer. According to one embodiment of the invention, the plasma treatment modifies a TaCₓ layer to a Ta/TaCₓ bilayer. According to another embodiment of the invention, the plasma treatment modifies a TaCₓN_{y} layer to a Ta/TaCₓN_{y} bilayer. As those of ordinary skill in the art will readily recognize, a clear boundary between the layers of the bilayer may not be discernable but rather a gradient in the elemental composition may be observed.

The plasma treating step 506 may be performed in the same process chamber as the deposition step 504. Alternately the plasma treating step 506 may be performed in a designated treatment chamber. In one example, the treatment chamber includes a SPA plasma source. A SPA plasma source is capable of forming a plasma characterized by low electron temperature (less than about 1.5 eV) and high plasma density (>1×10¹²/cm³), that enables substantially damage-free treating of the Ta-containing layer according to the invention. Such process parameters create a “soft plasma” that effectively reduces contaminants on the surface of the Ta-containing layer.

FIG. 5B is a flow diagram for depositing a Ta-containing layer on a substrate and treating the Ta-containing layer according to an embodiment of the invention. The process 510 starts in step 512. In step 514, a Ta-containing layer is deposited on a substrate from process gas containing a (CpR₁)(CpR₂)TaH(CO) precursor. The Ta-containing layer may be deposited by any of the processes 200, 300, 301 described in reference to FIGS. 2-3. In step 516, a portion of the Ta-containing layer is treated with plasma excited nitrogen-containing gas to increase the nitrogen content of the plasma treated portion of the Ta-containing layer. The nitrogen-containing gas can, for example, contain N₂, NH₃, or N₂H₄, or a combination thereof. Furthermore, the nitrogen-containing may contain a noble gas, H₂, or a combination thereof. In one example, the Ta-containing layer can be a TaCₓ layer and the plasma treated portion a TaCₓN_{y} layer or a TaN_{y} layer.

FIG. 5C is a flow diagram for depositing a Ta-containing layer on a substrate and treating the Ta-containing layer according to an embodiment of the invention. In FIG. 5C, the process 520 starts in step 522. In step 524, a Ta-containing layer is deposited on a substrate from a process gas containing a (CpR₁)(CpR₂)TaH(CO) precursor. The Ta-containing layer may be deposit by any of the processes 200, 300, 301 described in FIGS. 2-3. In step 526, a portion of the Ta-containing layer is treated with thermal nitrogen-containing gas to increase the nitrogen content of the treated portion of the Ta-containing layer. The nitrogen-containing gas can, for example, contain NH₃, N₂H₄, or a combination thereof. Furthermore, the nitrogen-containing may contain a noble gas, H₂, or a combination thereof. In one example, the Ta-containing layer can be a TaCₓ layer and the treated portion a TaCₓN_{y} layer or a TaN_{y} layer.

According to an embodiment of the invention, a second Ta-containing layer may be deposited onto the Ta-containing layer described in FIGS. 2-5. For example, the second Ta-containing layer may be deposited by an alternating exposure process including exposing a process gas comprising the (CpR₁)(CpR₂)TaH(CO) precursor to the substrate, and exposing the second Ta-containing layer to a plasma excited hydrogen-containing gas. The hydrogen-containing gas can contain H₂ and a noble gas. According to one embodiment of the invention, the Ta-containing layer may contain TaCₓ and the second Ta-containing layer may have a higher tantalum content than the first Ta-containing layer. According to another embodiment of the invention, the Ta-containing layer may contain TaCₓN_{y} and the second Ta-containing layer may have a higher tantalum content than the first Ta-containing layer.

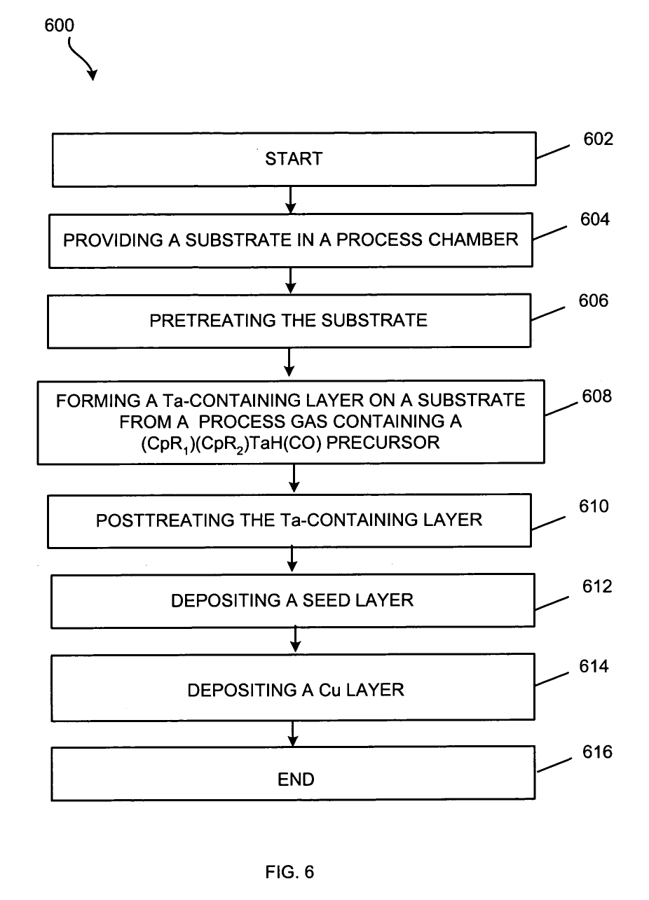

FIG. 6 is a process flow diagram for integrating a Ta-containing layer with Cu metallization according to an embodiment of the invention. The process 600 starts in step 602. In step 604, a substrate is provided in a process chamber. In step 606, the substrate is pretreated by degassing (heating) the substrate at reduced pressure, exposing the substrate to a cleaning plasma, or a combination of degassing and exposing the substrate to a cleaning plasma. The degassing may be performed in the presence of an inert gas and the cleaning plasma may utilize a reducing gas (e.g, H₂), an inert gas, or a combination thereof. The pretreating step 606 removes any oxide or other contaminants from the substrate surface in preparation for further processing. In step 608, a Ta-containing layer is formed on a substrate from a (CpR₁)(CpR₂)TaH(CO) precursor. The Ta-containing layer may be formed by any of the processes 200, 300, 301 and treated by any of the processes 510, 520, 530 described in FIGS. 2-5. In addition, the Ta-containing layer may contain a second Ta-containing layer as described above.

In step 610, the Ta-containing layer is posttreated by degassing (heating) the substrate at reduced pressure, exposing the Ta-containing layer to a cleaning plasma, or a combination of degassing and exposing the substrate to a cleaning plasma. The degassing may be performed in the presence of an inert gas and the treating plasma may utilize a reducing gas, a nitrogen-containing gas, an inert gas, or a combination thereof. In step 612, a seed layer is deposited on the posttreated Ta-containing layer. The seed layer can, for example, be a thin Cu or Ru layer deposited by PVD or TCVD. In step 614, a bulk Cu layer is deposited onto the seed layer. The bulk Cu layer may, for example, be deposited by electroplating, by electroless plating, or by CVD.

According to another embodiment of the invention, the post-treating step 610 may be omitted and a seed layer deposited following the formation of the Ta-containing layer.

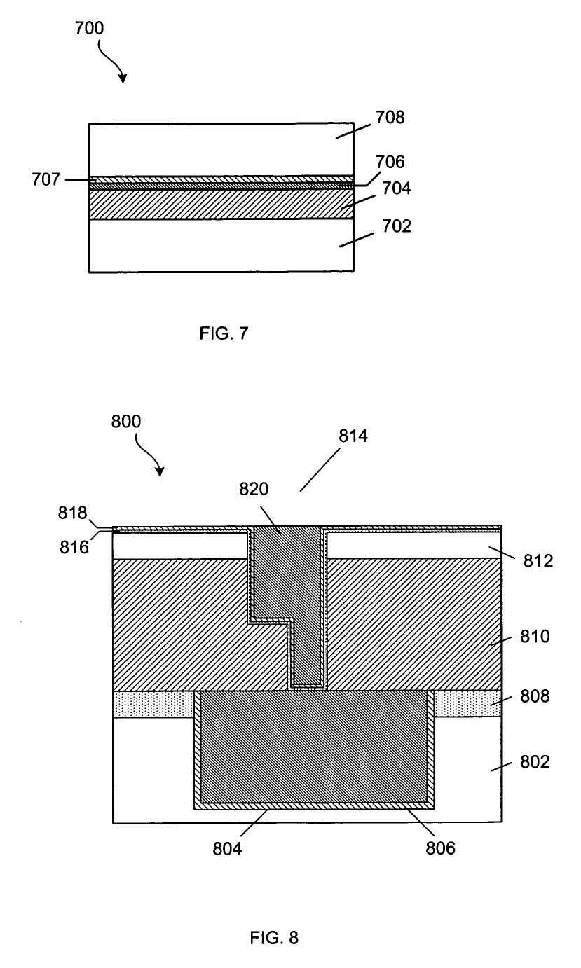

FIG. 7 depicts schematically integration of a Ta-containing layer with Cu metallization according to an embodiment of the invention. The integration process may utilize the process flow diagram depicted in FIG. 6 to form the structure 700. The structure 700 contains a substrate 702, a Ta-containing layer 704 containing a treated portion 706, a seed layer 706 (e.g., Cu or Ru), and a bulk Cu layer 708.

FIG. 8 depicts a schematic view a Ta-containing layer integrated with Cu metallization of a semiconductor structure according to an embodiment of the invention. The structure 800 contains a substrate layer 802 (e.g., SiO₂), a barrier layer 804, a conductor layer 806 (e.g., Cu), a mask layer 808 (e.g., SiCN), a low-k layer 810, an oxide layer 812 (e.g., SiO₂). The structure 800 further contains an opening 814, and a Ta-containing layer 816 formed from a (CpR₁)(CpR₂)TaH(CO) precursor. In one example, the Ta-containing layer 816 can contain a Ta/TaCₓ bilayer. In another example, the Ta-containing layer 816 can contain a Ta/TaCₓN_{y} bilayer. The structure 800 further contains a seed layer 818 (e.g., Ru or Cu) and the opening 814 contains a trench and a via filled with bulk Cu layer 820.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A method of processing a substrate, the method comprising:
providing the substrate in a process chamber; and
exposing the substrate to a process gas comprising a metalorganic tantalum precursor to form a Ta-containing layer on the substrate, wherein
the metalorganic tantalum precursor comprises Ta, a H ligand and a CO ligand; and
the metalorganic tantalum precursor has a vapor pressure at 100° C. in the range of from 0.1 to 3 torr.

2. The method according to claim 1, wherein the metalorganic tantalum precursor has the formula:
(CpR₁)(CpR₂)TaH(CO)
where:
Cp is a cyclopentadienyl functional group, and
R₁ and R₂ are independently selected from the group consisting of H and alkyl groups.

3. The method according to claim 2, wherein the alkyl groups are C₁-C₈ alkyl groups.

4. The method according to claim 2, wherein the alkyl groups are methyl, ethyl, n-propyl, isopropyl, and tert-butyl groups.

5. The method according to claim 2, wherein the metalorganic tantalum precursor comprises (CpCH₂CH₃)₂TaH(CO) or (Cp)₂TaH(CO).

6. The method according to claim 1, wherein the process gas further comprises N₂, noble gas, or a combination thereof.

7. The method according to claim 1, wherein the process gas further comprises H₂, SiH₄, B₂H₆, HCOOH, or a combination thereof.

8. The method according to claim 1, wherein the process gas further comprises a nitrogen-containing gas.

9. The method according to claim 8, wherein the nitrogen-containing gas comprises NH₃, N₂H₄, NH(CH₃)₂, or H₂N₂HCH₃, or a combination or two or more thereof.

10. The method according to claim 1, wherein the process gas further comprises TAIMATA.

11. The method according to claim 1, where the exposing comprises maintaining the substrate at a temperature between 150° C. and 600° C.

12. The method according to claim 1, wherein the exposing comprises subjecting the substrate to an alternating exposure process comprising:
exposing the process gas to the substrate to deposit the Ta-containing layer; and
exposing the Ta-containing layer to a hydrogen-containing gas.

13. The method according to claim 12, wherein the hydrogen-containing gas comprises H₂ and a noble gas.

14. The method according to claim 1, wherein the exposing comprises subjecting the substrate to an alternating exposure process comprising:
exposing the process gas to the substrate to deposit the Ta-containing layer; and
exposing the Ta-containing layer to a plasma excited hydrogen-containing gas.

15. The method according to claim 14, wherein the hydrogen-containing gas comprises H₂ and a noble gas.

16. The method according to claim 1, wherein the exposing comprises subjecting the substrate to an alternating exposure process comprising:
exposing the process gas to the substrate to deposit the Ta-containing layer; and
exposing the Ta-containing layer to a nitrogen-containing gas.

17. The method according to claim 16, wherein the nitrogen-containing gas comprises NH₃, N₂H₄, NH(CH₃)₂, or H₂N₂HCH₃, or a combination or two or more thereof.

18. The method according to claim 16, wherein the nitrogen-containing gas further comprises a noble gas, H₂, or a combination thereof.

19. The method according to claim 1, wherein the exposing comprises subjecting the substrate to an alternating exposure process comprising:
exposing the process gas to the substrate to deposit the Ta-containing layer; and
exposing the Ta-containing layer to a plasma excited nitrogen-containing gas.

20. The method according to claim 19, wherein the nitrogen-containing gas comprises N₂, NH₃, or a combination thereof.

21. The method according to claim 19, wherein the nitrogen-containing gas further comprises a noble gas, H₂, or a combination thereof.

22. The method according to claim 1, wherein the Ta-containing layer comprises tantalum metal, tantalum carbide, tantalum nitride, tantalum carbonitride, or a combination thereof.

23. The method according to claim 1, further comprising
treating the Ta-containing layer with a plasma excited hydrogen-containing gas to increase the tantalum content of the plasma treated portion of the Ta-containing layer.

24. The method according to claim 23, wherein the hydrogen-containing gas comprises H₂ and a noble gas.

25. The method according to claim 1, further comprising
treating the Ta-containing layer with a nitrogen-containing gas to increase the nitrogen content of the treated portion of the Ta-containing layer.

26. The method according to claim 25, wherein the nitrogen-containing gas comprises NH₃, N₂H₄, NH(CH₃)₂, or H₂N₂HCH₃, or a combination or two or more thereof.

27. The method according to claim 25, wherein the nitrogen-containing gas further comprises a noble gas, H₂, or a combination thereof.

28. The method according to claim 1, further comprising
treating the Ta-containing layer with a plasma excited nitrogen-containing gas to increase the nitrogen content of the plasma treated portion of the Ta-containing layer.

29. The method according to claim 28, wherein the nitrogen-containing gas comprises N₂, NH₃, or N₂H₄, or a combination thereof.

30. The method according to claim 28, wherein the nitrogen-containing gas further comprises a noble gas, H₂, or a combination thereof.

31. The method according to claim 1, wherein the Ta-containing layer is a first Ta-containing layer; and the method further comprises depositing a second Ta-containing layer onto the first Ta-containing layer by an alternating exposure process comprising:
exposing the process gas to the substrate to form a second Ta-containing layer on the first Ta-containing layer; and
exposing the second Ta-containing layer to a plasma excited hydrogen-containing gas.

32. The method according to claim 31, wherein the hydrogen-containing gas comprises H₂ and a noble gas.

33. The method according to claim 31, wherein the first Ta-containing layer comprises TaCₓ and the second Ta-containing layer has higher tantalum content than the first Ta-containing layer.

34. The method according to claim 31, wherein the first Ta-containing layer comprises TaCₓN_{y} and the second Ta-containing layer has higher tantalum content than the first Ta-containing layer.

35. The method according to claim 1, further comprising
depositing a seed layer on the Ta-containing layer; and
depositing a Cu layer on the seed layer.

36. The method according to claim 35, further comprising
posttreating the Ta-containing layer prior to depositing the seed layer,

37. The method according to claim 36, wherein the posttreating comprises:
degassing the substrate, exposing the Ta-containing layer to a cleaning plasma, or a combination thereof.

38. The method according to claim 35, wherein the seed layer comprises at least one selected from the group consisting of Cu and Ru.

39. A computer readable medium containing program instructions for execution on a substrate processing system processor, which when executed by the processor, cause the substrate processing system to perform the steps of the method recited in claim 1.

40. A semiconductor structure comprising a substrate processed by the method of claim 1.

41. The semiconductor structure according to claim 40, wherein the substrate contains at least one selected from the group consisting of vias and trenches.

42. The semiconductor structure according to claim 40, wherein the substrate comprises a low-k layer.
